(19) United States
(12) Patent Application Publication
(10) Pub. No.: US 2013/0334646 A1
(43) Pub. Date: Dec. 19, 2013

(54) METALLIC THERMAL SENSOR FOR IC DEVICES

(71) Applicant: Chung-Hui CHEN, HsinChu City (TW)

(72) Inventor: Chung-Hui CHEN, HsinChu City (TW)

(73) Assignee: TAIWAN SEMICONDUCTOR MANUFACTURING CO., LTD., Hsin-Chu (TW)

(21) Appl. No.: 13/525,415

(22) Filed: Jun. 18, 2012

(51) Int. Cl. H01L 27/16; G01K 7/01

(52) U.S. Cl. 257/467; 374/178; 257/E27.008; 374/E07.035

(57) ABSTRACT

A thermal sensor for use in an IC device is formed of a plurality of metal resistor units connected in series where each of the plurality of metal resistor units are formed on different wiring layers of the IC device connected by via segments and the metal resistor units are in a superimposed alignment with each other forming a stack.

### FIELD

The disclosed subject matter generally relates to temperature sensing structure for monitoring temperature in an integrated circuit (IC) devices.

### BACKGROUND

There exists a number of thermal sensing solutions for measuring and monitoring the temperature of IC devices. Some examples of such solutions in CMOS IC devices are diodes, bipolar junction transistors or MOSFET based on-chip thermal sensors. Some solutions involved a resistive metal line or wire of substantial length placed on a single metal layer or level of an IC device, in a serpentine pattern or configuration but constructing long serpentine lines on a single layer of the IC required large areas of the IC layer and reduced the wiring channels on that layer.

### BRIEF DESCRIPTION OF THE DRAWINGS

FIG. 1 is a plan view of an example of metal resistor units of a thermal sensor for an IC device according to an embodiment of the present disclosure.

FIG. 2A is a cross-sectional view of a stack formed by the four metal resistor units of FIG. 1 in superimposed alignment where the section is taken along the line A shown in FIG. 1.

FIG. 2B is another cross-sectional view of the stack shown in FIG. 2A where the section is taken along the line B shown in FIG. 1.

FIG. 3A is a generalized circuit diagram illustration of the thermal sensor of FIG. 1.

FIG. 3B is a generalized circuit diagram illustration of a thermal sensor according to another embodiment of the present disclosure.

FIG. 4 shows a resistance vs. bias voltage plot for metal resistor units from a SPICE simulation.

FIG. 5 shows a resistance vs. temperature plot for metal resistor units from a SPICE simulation.

All drawings are schematic and are not drawn to scale.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

According to an embodiment of the present disclosure, a thermal sensor for use in an IC device is formed of a plurality of metal resistor units connected in series where each of the plurality of metal resistor units are formed on different wiring layers of the IC device and the metal resistor units are in a superimposed alignment with each other forming a stack. For a given thermal sensor, the temperature coefficient of resistance (TCR) will be known and, thus, by measuring the electrical resistance of the stack, the temperature of the IC device can be determined. The TCR of a given thermal sensor is determined by the particular metal conductor used to form the metal resistor units and the dimensions of the metal resistor units.

Alternatively, the temperature of the IC device can be determined by measuring the voltage across the stack while a constant known current is flowing through the stack. In another alternative, the amount of current flowing through the stack can be measured while a constant voltage is maintained across the stack's terminal ends.

Each of the one or more metal resistor units in a given metal wiring layer is in a superimposed alignment with corresponding metal resistor units in the neighboring metal wiring layer, wherein each of the one or more metal resistor units has two terminal ends and a via segment connecting one of the two terminal ends of two adjacent superimposed metal resistor units.

According to another aspect, each of the metal resistor units has a length of 10 to 10000 μm and the width of the metal lines forming the metal resistor units is between a desired minimum width to 3 times the desired minimum width, and the spacing between the metal lines forming the metal resistor units is between a desired minimum spacing to 3 times the desired minimum spacing.

According to another embodiment of the present disclosure, an integrated circuit device is disclosed. The integrated circuit device comprises a wiring structure wherein the wiring structure has a plurality of metal wiring layers and via layers and at least one thermal sensor. The thermal sensor comprises one or more metal resistor units provided in each of the plurality of metal wiring layers and forms one or more metal resistor stacks, wherein each of the one or more metal resistor units in a given metal wiring layer is in a superimposed alignment with corresponding metal resistor units in the neighboring metal wiring layer. Each of the one or more metal resistor units has two terminal ends and a via segment connecting one of the two terminal ends of two adjacent superimposed metal resistor units.

According to an aspect of the present disclosure, each of the metal resistor units has a length of 10 to 10000 μm and the width of the metal lines forming the metal resistor units is between a desired minimum width to 3 times the desired minimum width, and the spacing between the metal lines forming the metal resistor units is between a desired minimum spacing to 3 times the desired minimum spacing.

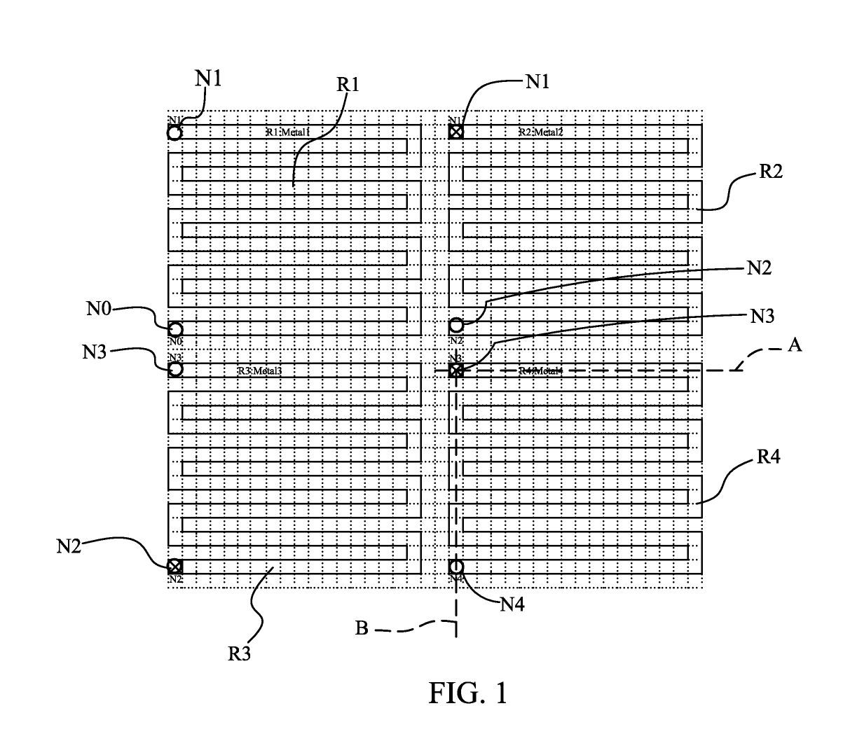

FIG. 1 shows metal resistor units for a thermal sensor for an IC device according to an embodiment. In this example, the thermal sensor comprises four metal resistor units R1, R2, R3, and R4. But as mentioned above, a thermal sensor according to the scope of the present disclosure can comprise a plurality of metal resistor units electrically connected in series. Each of the four metal resistor units are formed on different wiring layers of the IC device. For example, the metal resistor units R1, R2, R3, and R4 can be formed on four consecutively arranged wiring layers M1, M2, M3, and M4, respectively. The wiring layer designations Ml, M2, M3, and M4 here follow the general Mx naming convention for wiring layers on IC devices where x is an integer. M1 is the lowest wiring layer (i.e., closest to the IC device's device layer) and M4 is the highest layer (i.e., the wiring layer closest to the surface). Although each of the metal resistor units R1, R2, R3, and R4 can have different unique serpentine patterns, in one embodiment, the metal resistor units R1, R2, R3, and R4 have the same serpentine pattern. Having the same serpentine pattern has a benefit of simplifying the manufacturing process and thus generally helpful in reducing manufacturing defects and increase yield.

According to an aspect of the present disclosure, the metal resistor units have a convoluted configuration to enable the metal resistor units to have a sufficiently long length to have a sufficiently high electrical resistance while occupying a minimum area on the IC device.

In the example shown in FIG. 1, the metal resistor units have a serpentine pattern having seven folds. This is because if the electrical resistance of the metal resistor units is too low, it will not have sufficient temperature sensitivity to be useful as a temperature sensor. In the example illustrated in FIG. 1, the metal resistor units R1, R2, R3, and R4 have a serpentine configuration. According to another embodiment, the metal resistor units can be a simple stripe or any other shape that will provide the desired electrical resistance.

The desired electrical resistance for a metal resistor unit is a sheet resistance of 0.5 to 10 Ω/□.

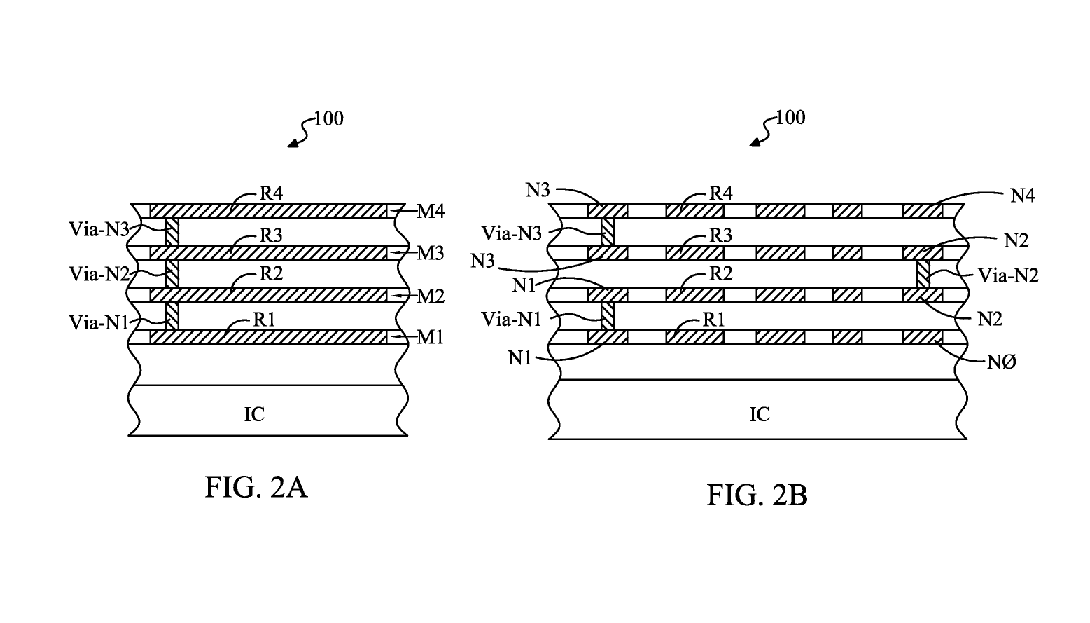

Each of the metal resistor units have two terminal ends and the metal resistor units are connected in series by a via providing the connection between the metal resistor units in the series. This is shown in the cross-sectional views of FIGS. 2A and 2B. FIG. 2A is a cross-sectional view of a thermal sensor 100 formed by a stack of the four metal resistor units of FIG. 1 in a superimposed alignment where the section is taken along the line A shown in FIG. 1. The thermal sensor 100 and the associated wiring layers M1, M2, M3, and M4 are part of the integrated circuit device IC. FIG. 2B is another cross-sectional view of the thermal sensor 100 where the section is taken along the line B shown in FIG. 1.

The metal resistor unit R1 has terminal ends N0 and N1. The metal resistor unit R2 has terminal ends N1 and N2. The metal resistor unit R3 has terminal ends N2 and N3. The metal resistor unit R4 has terminal ends N3 and N4. The terminal end N1 of the metal resistor unit R1 is connected to the terminal end N1 of the metal resistor unit R2 by a via segment Via-N1. The terminal end N2 of the metal resistor unit R2 is connected to the terminal end N2 of the metal resistor unit R3 by a via segment Via-N2. The terminal end N3 of the metal resistor unit R3 is connected to the terminal N3 of the metal resistor unit R4 by a via segment Via-N3.

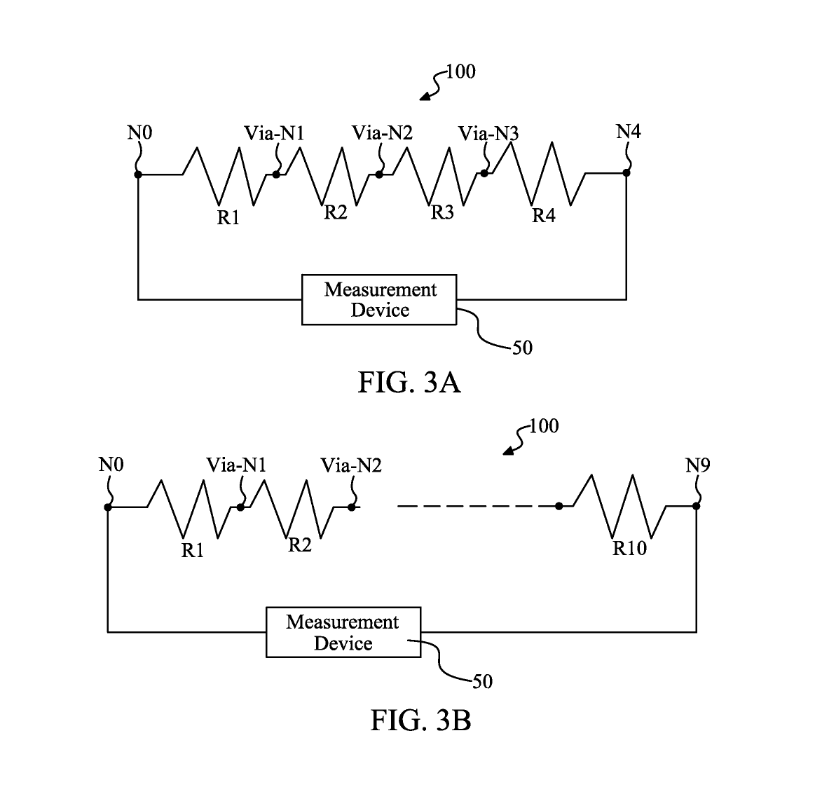

FIG. 3A is a schematic circuit diagram showing the four metal resistor units R1, R2, R3, and R4 connected in series and forming the thermal sensor 100. Using a suitable measurement device 50 connected to the thermal sensor 100 as shown, the temperature of the IC device can be measured. The measurement device 50 can be a voltmeter, a volt meter, or an ammeter depending on whether the electrical resistance of the thermal sensor 100, the voltage across the thermal sensor 100, or the current through the thermal sensor 100 is to be measured.

FIG. 3B is a schematic circuit diagram showing a generalized embodiment of the thermal sensor 100 according to an aspect of the present disclosure. The thermal sensor 100 can have one metal resistor unit R1, . . . R10 provided in each of the plurality of wiring layers M1, . . . M10 to form a metal resistor stack. In another embodiment, two or more metal resistor units are provided in each of the plurality of wiring layers M1, . . . M10 to form a metal resistor stack. In such embodiment, each wiring layer would have the same number of metal resistor units. For example, a thermal sensor can be formed from six wiring layers M1 through M6 with each wiring layer having three metal resistor units (i.e., M1 would have metal resistor units R1a, R1b, R1c; M2 would have metal resistor units R2a, R2b, R2c, . . .) connected in series. Thus the metal resistor stack in that embodiment would have a total of eighteen metal resistor units connected in series. The metal resistor units can be provided in one or more of the wiring layers in a given IC device and can be provided in every wiring layer in a given IC device if necessary.

The superimposed alignment means that the metal resistor units are vertically aligned over one another so that the metal resistor units are superimposed over one another in the direction orthogonal to the plane of the metal wiring layers. By superimposing the metal resistor units the footprint of the metal resistor units are minimized on the IC device and make more of the wiring layers' areas available for the IC device's functional wiring.

According to an embodiment, each of the metal resistor units, such as R1 to R10 have a length of 10 to 10000 μm and the width of the metal lines forming the metal resistor units is between a desired minimum width, Wmin, to 3 times the Wmin. The spacing between the metal lines forming the metal resistor units is between a desired minimum spacing, Smin, to 3 times the Smin. Generally, Wmin will be the minimum width dimension allowed by the design rule for the particular IC technology and Smin will be the minimum spacing dimension between the metal features allowed by the design rule for the particular IC technology.

According to an aspect of the present disclosure, Wmin is 5 to 32 nm, and Smin is 5 to 32 nm. The sheet resistance of the metal thin films forming the metal resistor units is between 0.5 to 10 Ω/58 .

Since the Wmin and Smin is so small, the resistance can be very high, comparing with the prior art. Higher resistance can generate higher resistance change and voltage change for thermal sensor to detect, thus creating smaller area, more precise thermal sensor.

These dimensional features for the metal resistor units help minimize the footprint of the metal resistor units. The compact dimensions of the metal resistor units allow the thermal sensors of the present disclosure to be placed in IC devices with high density of active circuits such as microprocessor IC devices without too much hindrance. According to another aspect, because of the compactness of the thermal sensors of the present disclosure, multiple thermal sensors can be placed throughout the IC device to monitor the IC temperature in key areas of the IC device. The dimensional features for the metal resistor units keeping the metal lines close to the Wmin and Smin values also help with designing metal resistor units with suitable electrical resistance to be used as thermal sensors.

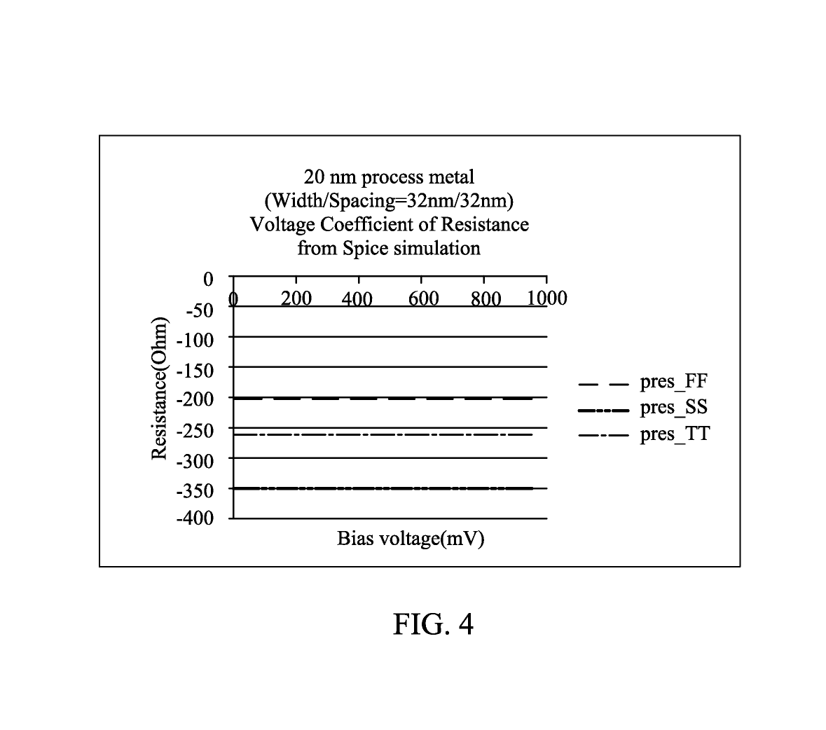

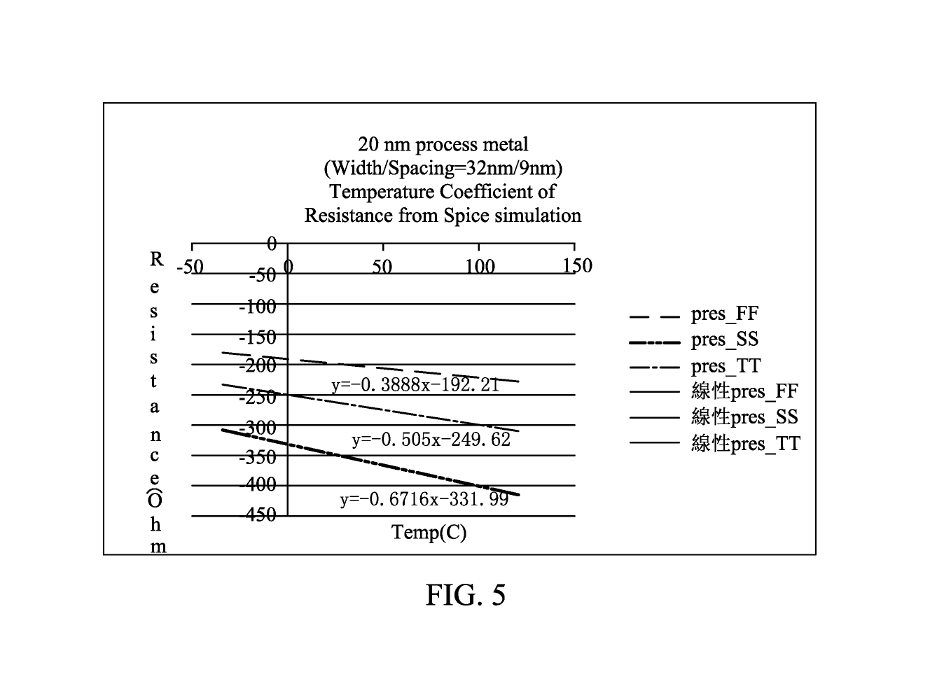

The inventor has conducted a SPICE simulation to verify that the metal resistor units according to the present disclosure would have negligible voltage coefficient of resistance (VCR) and stable temperature coefficient of resistance (TCR) to be useful as a thermal sensor by cond. The SPICE simulation was conducted for metal wiring layer parameters for 20 nm lithography process. FIG. 4 shows the resistance vs. bias voltage simulation plots for fast process (“pres_FF”), slow process (“pres_SS”), and typical process (“pres_TT”) conditions. The plots show that the metal resistor units would have a negligible VCR. FIG. 5 shows the resistance vs. temperature simulation plots for the same fast process, slow process, and typical process conditions. The plots show that the metal resistor units would have a very stable TCR suitable for use as thermal sensors.

Although the subject matter has been described in terms of exemplary embodiments, it is not limited thereto. Rather, the appended claims should be construed broadly, to include other variants and embodiments, which may be made by those skilled in the art.

What is claimed is:

1. A thermal sensor for use in an integrated circuit device's wiring structure wherein the wiring structure has a plurality of metal wiring layers and via layers, the thermal sensor comprising:
one or more metal resistor units provided in each of the plurality of metal wiring layers and forming one or more metal resistor stacks, wherein each of the one or more metal resistor units in a given metal wiring layer is in a superimposed alignment with corresponding metal resistor units in the neighboring metal wiring layer, wherein each of the one or more metal resistor units has two terminal ends; and
a via segment connecting one of the two terminal ends of two adjacent superimposed metal resistor units.

2. The thermal sensor of claim 1, wherein each of the metal resistor units has a length of 10 to 10000 μm and the width of the metal lines forming the metal resistor units is between a desired minimum width to 3 times the desired minimum width, and the spacing between the metal lines forming the metal resistor units is between a desired minimum spacing to 3 times the desired minimum spacing.

3. The thermal sensor of claim 1, wherein the metal resistor units in a given metal resistor stack have the same pattern.

4. The thermal sensor of claim 3, wherein the metal resistor units in a given metal resistor stack have a convoluted pattern.

5. The thermal sensor of claim 3, wherein the convoluted pattern is a serpentine pattern.

6. The thermal sensor of claim 1, wherein the desired minimum width is 5 to 32 nm.

7. The thermal sensor of claim 1, wherein the desired minimum spacing is 5 to 32 nm.

8. The thermal sensor of claim 1, wherein the metal resistor units formed from metal thin films having a sheet resistance between 0.5 to 10 Ω/□.

9. A thermal sensor for use in an integrated circuit device's wiring structure wherein the wiring structure has a plurality of metal wiring layers and via layers, the thermal sensor comprising:
one or more metal resistor units provided in each of the plurality of metal wiring layers and forming one or more metal resistor stacks, wherein each of the one or more metal resistor units in a given metal wiring layer is in a superimposed alignment with corresponding metal resistor units in the neighboring metal wiring layer, wherein each of the one or more metal resistor units has two terminal ends; and
a via segment connecting one of the two terminal ends of two adjacent superimposed metal resistor units,
wherein each of the metal resistor units has a length of 10 to 10000 μm and the width of the metal lines forming the metal resistor units is between a desired minimum width to 3 times the desired minimum width, and the spacing between the metal lines forming the metal resistor units is between a desired minimum spacing to 3 times the desired minimum spacing.

10. The thermal sensor of claim 9, wherein the metal resistor units in a given metal resistor stack have the same pattern.

11. The thermal sensor of claim 10, wherein the metal resistor units in a given metal resistor stack have a convoluted pattern.

12. The thermal sensor of claim 10, wherein the convoluted pattern is a serpentine pattern.

13. The thermal sensor of claim 9, wherein the desired minimum width is 5 to 32 nm.

14. The thermal sensor of claim 9, wherein the desired minimum spacing is 5 to 32 nm.

15. The thermal sensor of claim 9, wherein the metal resistor units formed from metal thin films having a sheet resistance between 0.5 to 10 Ω/□.

16. An integrated circuit device comprising:
a wiring structure wherein the wiring structure has a plurality of metal wiring layers and via layers; and
a thermal sensor comprising:
one or more metal resistor units provided in each of the plurality of metal wiring layers and forming one or more metal resistor stacks, wherein each of the one or more metal resistor units in a given metal wiring layer is in a superimposed alignment with corresponding metal resistor units in the neighboring metal wiring layer, wherein each of the one or more metal resistor units has two terminal ends; and
a via segment connecting one of the two terminal ends of two adjacent superimposed metal resistor units,
wherein each of the metal resistor units has a length of 10 to 10000 μm and the width of the metal lines forming the metal resistor units is between a desired minimum width to 3 times the desired minimum width, and the spacing between the metal lines forming the metal resistor units is between a desired minimum spacing to 3 times the desired minimum spacing.

17. The thermal sensor of claim 16, wherein the metal resistor units in a given metal resistor stack have the same pattern.

18. The thermal sensor of claim 17, wherein the metal resistor units in a given metal resistor stack have a convoluted pattern.

19. The thermal sensor of claim 17, wherein the convoluted pattern is a serpentine pattern.

20. The thermal sensor of claim 16, wherein the desired minimum width is 5 to 32 nm and the desired minimum spacing is 5 to 32 nm.
